(19) United States
(12) Patent Application Publication
(10) Pub. No.: US 2024/0304624 A1
(43) Pub. Date: Sep. 12, 2024

(54) metal-oxide-semiconductor transistor and complementary metal-oxide-semiconductor circuit related

(71) Applicant: Invention and Collaboration Laboratory, Inc., Taipei City (TW)

(72) Inventor: Chao-Chun Lu, Taipei City (TW)

(73) Assignee: Invention and Collaboration Laboratory, Inc., Taipei City (TW)

(21) Appl. No.: 18/599,239

(22) Filed: Mar. 8, 2024

Related U.S. Application Data
(60) Provisional application No. 63/451,236, filed on Mar. 10, 2023.

(51) Int. Cl. H01L 27/092; H01L 29/06; H01L 29/66

(52) U.S. Cl. CPC H01L 27/092; H01L 29/0642; H01L 29/6656

(57) ABSTRACT

A CMOS circuit includes a bulk semiconductor substrate, a first active region, a PMOS second active region, a (p-type Metal-Oxide-Semiconductor) transistor, a first localized isolating layer, an NMOS (n-type Metal-Oxide-Semiconductor) transistor formed in the second active region, and a second localized isolating layer. The bulk semiconductor substrate has an original semiconductor surface. The first active region and the second active region are formed based on the bulk semiconductor substrate. The PMOS transistor is formed in the first active region. The first localized isolating layer is under the PMOS transistor and at least partially isolates the PMOS transistor from the bulk semiconductor substrate. The NMOS transistor is formed in the second active region. The second localized isolating layer is under the NMOS transistor and at least partially isolates the NMOS transistor from the bulk semiconductor substrate.

### CROSS REFERENCE TO RELATED APPLICATIONS

This application claims the benefit of U.S. Provisional Application No. 63/451, 236, filed on Mar. 10, 2023. The content of the application is incorporated herein by reference.

### BACKGROUND OF THE INVENTION

### 1. Field of the Invention

The present invention relates to an Oxide-PMOS Complementary Metal-Oxide-Semiconductor Field-Effect Transistor (OP-CMOSFET) structure, and particularly to an OP-CMOSFET structure which can have lower cost, improve leakage current and latch up issues in the CMOS structure, solve floating body effect in the conventional SOI (Silicon Over Isolator) wafer, no ion-implantation process for doping the Source/Drain regions, and reduce leakage currents.

### 2. Description of the Prior Art

MOS (Metal-Oxide-Semiconductor) transistor circuit, such as Complementary Metal-Oxide-Semiconductor Field-Effect Transistors (CMOSFET) , is widely employed in semiconductor industry. FIG. 1 shows a cross-section view of a state-of-the-art CMOSFET which is most widely used in today's Integrated Circuits (IC). The CMOSFET includes an NMOS (n-type Metal-Oxide-Semiconductor) transistor and a PMOS (p-type Metal-Oxide-Semiconductor) transistor, wherein a Shallow Trench Isolation (STI) region is positioned between the NMOS transistor and the PMOS transistor. The gate structure of the NMOS transistor or the PMOS transistor using some conductive material (like metal, polysilicon or polyside, etc.) over an insulator (such as oxide, oxide/nitride or some high-k dielectric, etc.) is formed on a top of either a planar (planar CMOS) or a 3D silicon surface (such as, Tri-gate or FinFET or Gate-All-Around “GAA” CMOS) whose sidewalls are isolated from those of other transistors by using insulation materials (e.g. oxide or oxide/nitride or other dielectrics). For the NMOS transistor, there are source and drain regions which are formed by an ion-implantation plus thermal annealing technique to implant n-type dopants into a p-type substrate (or a p-well) which thus results in two separated n+/p junction areas. For the PMOS transistor, both source and drain regions are formed by ion-implanting p-type dopants into an n-well which thus results in two p+/n junction areas. Furthermore, to lessen impact ionization and hot carrier injection prior to highly doped n+/p or p+/n junction, it is common to form a lightly doped-drain (LDD) region under the gate structure.

Since the NMOS transistor and the PMOS transistor are located respectively inside some adjacent regions of p-substrate and n-well which have been formed next to each other within a close neighborhood, a parasitic junction structure called n+/p/n/p+ (the path marked by dash line in FIG. 1 is called as n+/p/n/p+ Latch-up path) parasitic bipolar device is formed with its contour starting from the n+ region of the NMOS transistor to the p-well to the neighboring n-well and further up to the p+ region of the PMOS transistor.

Once there are significant noises occurred on either n+/p junctions or p+/n junctions, an extraordinarily large current may flow through this n+/p/n/p+ junction abnormally which can possibly shut down some operations of CMOS circuits and to cause malfunction of the entire chip. Such an abnormal phenomenon called Latch-up is detrimental for CMOS operations and must be avoided. One way to increase the immunity to Latch-up which is certainly a weakness for CMOS is to increase the distance from n+ region to the p+ region (labeled as Latch-up Distance in FIG. 1) and both n+and p+ regions must be designed to be isolated by some vertically oriented oxide (or other suitable insulator materials) as isolation regions which is usually the STI (Shallow Trench Isolation) region. More serious efforts to avoid Latch-up must design a guard-band structure which further increases the distance between n+ regions and p+ regions and/or must add extra n+ regions or p+ regions to collect abnormal charges from noise sources. These isolation schemes always increase extra planar areas to sacrifice the die size of CMOS circuits.

On the other hand, the advancement of CMOS technologies is continuing to move forward rapidly by scaling down the geometries of devices in both horizontal and vertical dimensions (such as the minimum feature size called as Lamda (A) is shrunk from 28 nm down to 5 nm or 3 nm). The transistor structure has also changed from planar transistors to 3D transistor (such as either the Tri-gate or the FinFET structure using a convex channel called as a finger FET structure, a U-groove FET structure using a concave channel, etc.). But many problems are introduced or getting worse due to such device-geometry scaling:
(1) Scaling down the gate/channel length aggravates the Short Channel Effects (SCE), that is, the leakage currents related to the transistor channel are increased even at the turn-off mode of the transistor as the n+ source region is getting closer to the n+ drain region in NMOS (called as Sub-threshold Leakage current) and similarly for PMOS as the p+ source region is getting closer to the p+ drain region.
(2) All junction leakages resulted by junction formation processes such as forming LDD (Lightly Doped Drain) structure into the substrate/well regions, n+ Source/Drain structures into p-substrate and p+ Source/Drain structures into n-well are getting worse to control since leakage currents occur through both perimeter and bottom areas where extra damages like vacant traps for holes and electrons are harder to be repaired due to lattice imperfections which have been created by ion-implantation.

(3) Since the vertical length of STI structures is harder to be made deeper while the planar width of the device isolation must be scaled down (otherwise a worse depth-to-opening aspect ratio were created for integrated processes of making etching, filling and planarization), the proportional ratio of the planar isolation distance between the n+ and p+ regions of the neighbor transistors which is reserved for preventing Latch-up to the shrunken λ cannot be reduced but increased so as to hurt the die area reduction when scaling down CMOS devices.

Thus, transistors having a Silicon Over Isolator (SOI) structure are widely used to improve the short channel effect and latch-up issue. The SOI structure includes a bottom semiconductor substrate, an isolating substrate all over the surface of the bottom semiconductor substrate, and a top silicon layer all over the isolating substrate, wherein the CMOS devices or transistors are disposed in the top silicon layer. Such isolating substrate in SOI could isolate the bottom semiconductor substrate from the CMOS devices or transistors in the top silicon layer. The CMOS devices or transistors in the SOI structure have capabilities to reduce a short channel effect and the latch up issue, and operates at high speed while power consumption is small. However, the manufacture cost for CMOS devices or transistors in SOI structure is higher than that for CMOS devices or transistors in bulk semiconductor substrate. To be worse, the CMOS devices or transistors in SOI structure has a problem of a floating body effect. The transistor in SOI structure creates a capacitor over the isolating substrate, and charge accumulates on this capacitor may cause adverse effects, such as higher current consumption. And such floating body effect is worse in NMOS.

Therefore, how to design a new structure for the CMOS devices or transistors to improve the short channel effect and latch-up issue has become an important issue for a designer of the CMOS devices or transistors.

### SUMMARY OF THE INVENTION

An embodiment of the present invention provides a MOS (Metal-Oxide-Semiconductor) transistor. The MOS transistor includes a bulk semiconductor substrate, an active region, a gate structure, a transistor body, a source region, a drain region, and a localized isolating layer. The bulk a semiconductor substrate has semiconductor surface. The active region is defined based on the bulk semiconductor substrate. The gate structure is within the active region and above the semiconductor surface. The transistor body is within the active region and under the semiconductor surface. The source region is electrically coupled to a channel region within the transistor body. The drain region is electrically coupled to the channel region within the transistor body. The localized isolating layer extends along the length of the active region and under the transistor body. The localized isolating layer at least partially isolates the transistor body from the bulk semiconductor substrate, and a bottom of the source region and a bottom of the drain region abut against the localized isolating layer.

According to one aspect of the present invention, a vertical length of the transistor body is 5˜10 nm, and a length of the active region is greater than a width of the active region.

According to one aspect of the present invention, the localized isolating layer fully isolates the transistor body from the bulk semiconductor substrate.

According to one aspect of the present invention, the localized isolating layer has a semiconductor opening from which the transistor body is electrically coupled to the bulk semiconductor substrate.

According to one aspect of the present invention, a width of the semiconductor opening along the length of the active region is 1˜3 nm.

According to one aspect of the present invention, the MOS transistor further includes a shallow trench isolation region surrounding the active region and the localized isolating layer.

According to one aspect of the present invention, the MOS transistor further includes a spacer structure at least partially surrounding the active region, wherein the spacer structure is encompassed by the shallow trench isolation region.

According to one aspect of the present invention, spacer structure comprises a oxide spacer surrounding the active region and a nitride spacer surrounding the oxide spacer.

Another embodiment of the present invention provides a CMOS circuit. The CMOS circuit includes a bulk semiconductor substrate, a first active region, a second active region, a PMOS (p-type Metal-Oxide-Semiconductor) transistor, a first localized isolating layer, an NMOS (n-type Metal-Oxide-Semiconductor) transistor formed in the second active region, and a second localized isolating layer. The bulk semiconductor substrate has an original semiconductor surface. The first active region and the second active region are formed based on the bulk semiconductor substrate. The PMOS transistor is formed in the first active region. The first localized isolating layer is under the PMOS transistor and at least partially isolates the PMOS transistor from the bulk semiconductor substrate. The NMOS transistor is formed in the second active region. The second localized isolating layer is under the NMOS transistor and at least partially isolates the NMOS transistor from the bulk semiconductor substrate.

According to one aspect of the present invention, the CMOS circuit further includes a first shallow trench isolation region and a second shallow trench isolation region. The first shallow trench isolation region surrounds the first active region and the first localized isolating layer. The second shallow trench isolation region surrounds the second active region and the second localized isolating layer.

According to one aspect of the present invention, the first localized isolating layer fully isolates the PMOS transistor from the bulk semiconductor substrate, and the second localized isolating layer only partially isolates the NMOS transistor from the bulk semiconductor substrate.

According to one aspect of the present invention, the second localized isolating layer has a semiconductor opening from which the NMOS transistor body is electrically coupled to the bulk semiconductor substrate.

According to one aspect of the present invention, the first localized isolating layer only partially isolates the PMOS transistor from the bulk semiconductor substrate, and the second localized isolating layer fully isolates the NMOS transistor from the bulk semiconductor substrate.

According to one aspect of the present invention, the first localized isolating layer has a semiconductor opening from which the PMOS transistor body is electrically coupled to the bulk semiconductor substrate.

According to one aspect of the present invention, the first localized isolating layer fully isolates the PMOS transistor from the bulk semiconductor substrate, and the second localized isolating layer fully isolates the NMOS transistor from the bulk semiconductor substrate.

According to one aspect of the present invention, a length of the first active region is greater than a width of the first active region, and the first localized isolating layer extends along the length of the first active region; and a length of the second active region is greater than a width of the second active region, and the second localized isolating layer extends along the length of the second active region.

According to one aspect of the present invention, the PMOS transistor comprises a transistor body under the original semiconductor surface, and a vertical length of the transistor body is 5˜10 nm.

According to one aspect of the present invention, a bottom of the transistor body abuts against the first localized isolating layer.

Another embodiment of the present invention provides a CMOS circuit. The CMOS circuit includes a bulk semiconductor substrate, a set of PMOS transistors, and a set of NMOS transistors. The bulk semiconductor substrate has a first active region and a second active region. The set of PMOS transistors is formed in the first active region. The set of NMOS transistors is formed in the second active region. A first localized isolation layer extends along the length of the first active region and at least partially isolates the PMOS transistors from the bulk semiconductor substrate. A second localized isolation layer extends along the length of the second active region and at least partially isolates the NMOS transistors from the bulk semiconductor substrate.

According to one aspect of the present invention, the first localized isolating layer fully isolates the set of PMOS transistors from the bulk semiconductor substrate, and the second localized isolating layer only partially isolates the set of NMOS transistors from the bulk semiconductor substrate.

According to one aspect of the present invention, a first STI (shallow trench isolation) region surrounds the first active region, and a second STI region surrounds the second active region.

According to one aspect of the present invention, the CMOS circuit is a SRAM (static random-access memory) cell, and the distance between one PMOS transistor and one NMOS transistor adjacent to the one PMOS transistor is not greater than 3 F, wherein F is the minimum feature size.

According to one aspect of the present invention, a length of the first active region is greater than a width of the first active region, and a length of the second active region is greater than a width of the second active region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a state-of-the-art CMOS which includes a p-type metal-oxide-semiconductor (PMOS) transistor and an n-type metal-oxide-semiconductor (NMOS) transistor.

FIG. 2A is a flowchart illustrating an Oxide-PMOS Complementary Metal-Oxide-Semiconductor Field-Effect Transistor (OP-CMOSFET) structure based on a bulk semiconductor substrate according to one embodiment of the present invention.

FIG. 2B, FIG. 2C, FIG. 2D are diagrams illustrating FIG. 2A.

FIG. 3 is a diagram illustrating defining an active region of the OP-CMOSFET based on a semiconductor substrate.

FIG. 4, FIG. 5, FIG. 6, FIG. 7, FIG. 8, FIG. 9, FIG. 10, FIG. 11 are diagrams illustrating forming localized isolating layer under the active region of the OP-CMOSFET.

FIG. 12, FIG. 13, FIG. 14 are diagrams illustrating forming a gate region above the active region of the OP-CMOSFET.

FIG. 15, FIG. 16, FIG. 17, FIG. 18, FIG. 19 are diagrams illustrating forming a source region and a drain region in the active region of the OP-CMOSFET.

FIG. 20, FIG. 21, FIG. 22, FIG. 23 are diagrams illustrating various localized isolating layers under the active region of the OP-CMOSFET. active region of the OP-CMOSFET.

FIG. 24 is a diagram illustrating 6 T SRAM structure.

FIG. 25 is a diagram illustrating a layout of the 6 T CMOS SRAM cell.

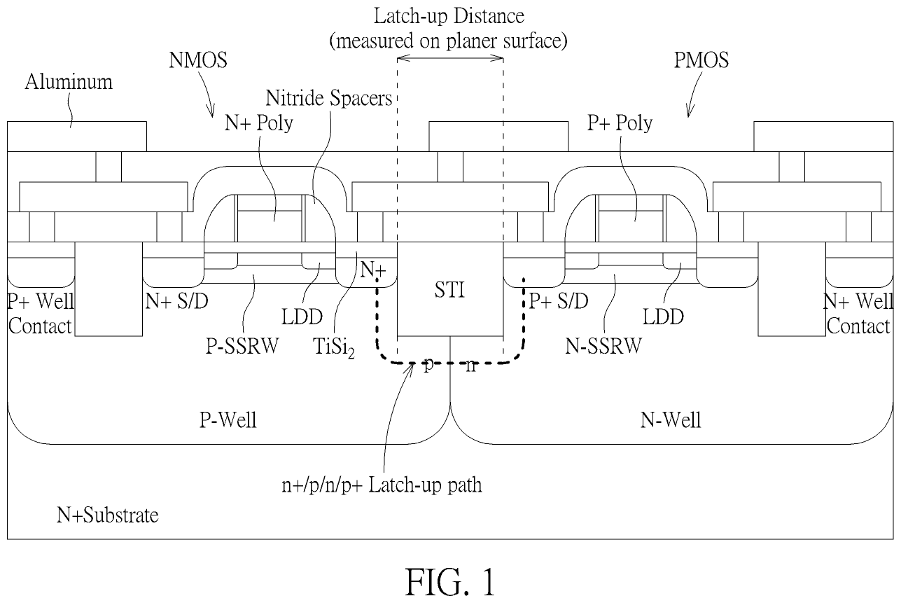

### DETAILED DESCRIPTION

This invention discloses a novel Oxide-PMOS Complementary Metal-Oxide-Semiconductor Field-Effect Transistor (OP-CMOSFET or OPCMOS) structure based on a bulk semiconductor substrate, rather than a SOI (Silicon On Insulator) structure, with localized isolating layers formed under the PMOS (p-type Metal-Oxide-Semiconductor) and NMOS (n-type Metal-Oxide-Semiconductor), respectively. Wherein, the localized isolating layer under the PMOS fully isolates the PMOS active region body from the bulk semiconductor substrate, but the localized isolating layer under the NMOS may not fully isolate the NMOS active region body from the bulk semiconductor and leave an opening from which the electrons accumulated in the NMOS active region body could leak into the bulk semiconductor substrate to improve the floating body effect. Thus, the present invention greatly improves or even solved most of the problems as stated above in terms of further enhancing CMOS designs during both device and circuit scaling, especially minimizing t leakages, increasing channel-conduction performance and control, increasing higher immunity of the CMOS circuits against Latch-up and minimizing the floating body effect.

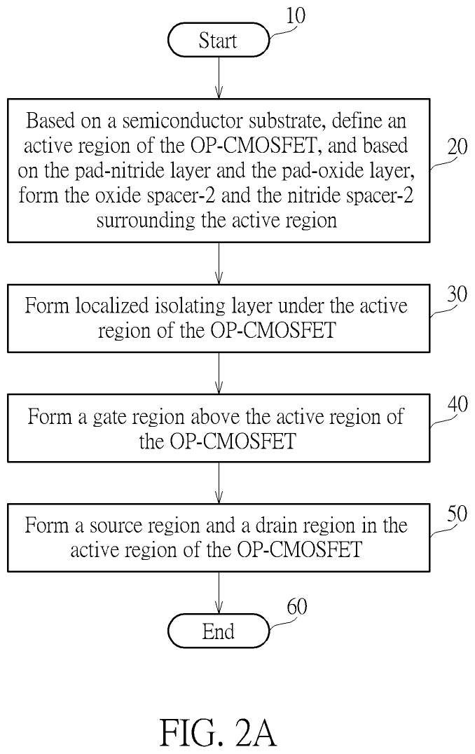

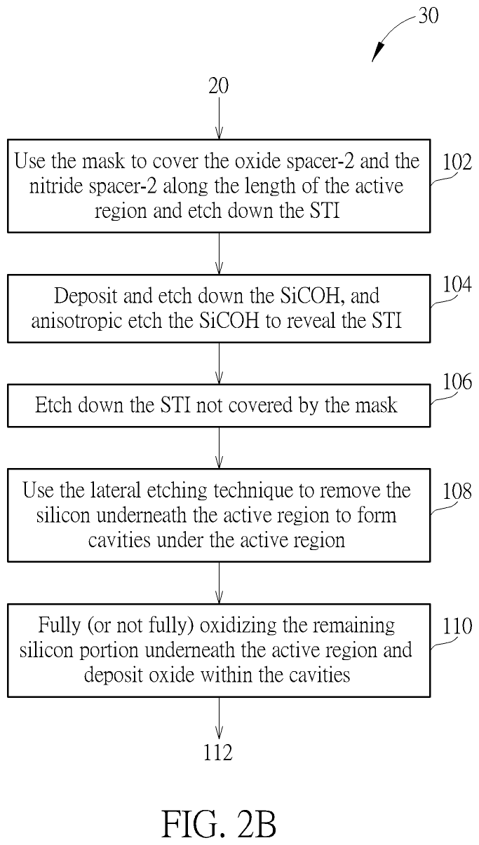

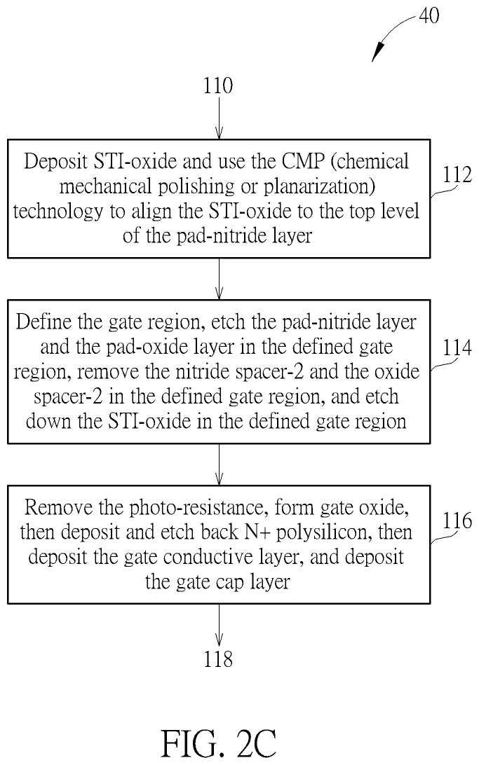

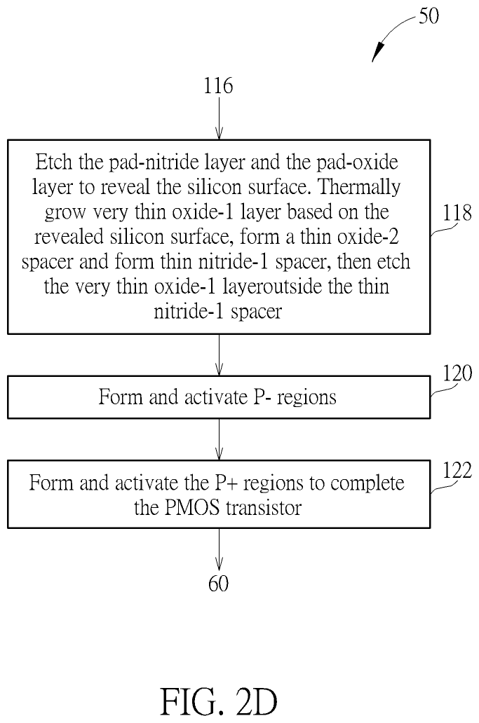

Next, the OP-CMOSFET can be achieved by a manufacture method described in FIG. 2A. Detailed Steps are as follows:

Step 10: Start.

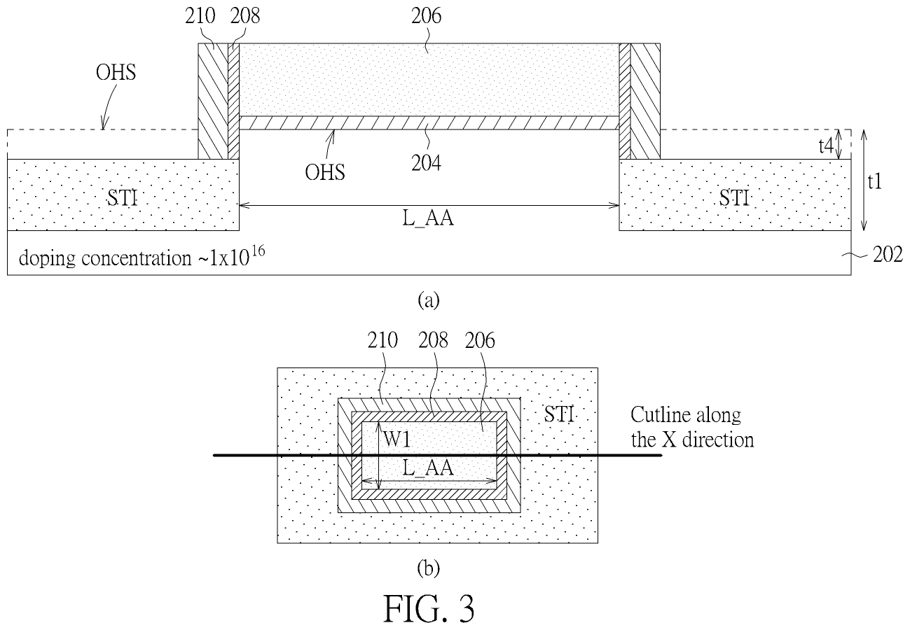

Step 20: Based on a semiconductor substrate, define an active region of the OP-CMOSFET based on the pad-nitride layer 206 and the pad-oxide layer 204, and form the oxide spacer-2 208 and the nitride spacer-2 210 surrounding the active region (FIG. 3).

Step 30: Form localized isolating layer under the active region of the OP-CMOSFET.

Step 40: Form a gate region above the active region of the OP-CMOSFET.

Step 50: Form a source region and a drain region in the active region of the OP-CMOSFET.

Step 60: End.

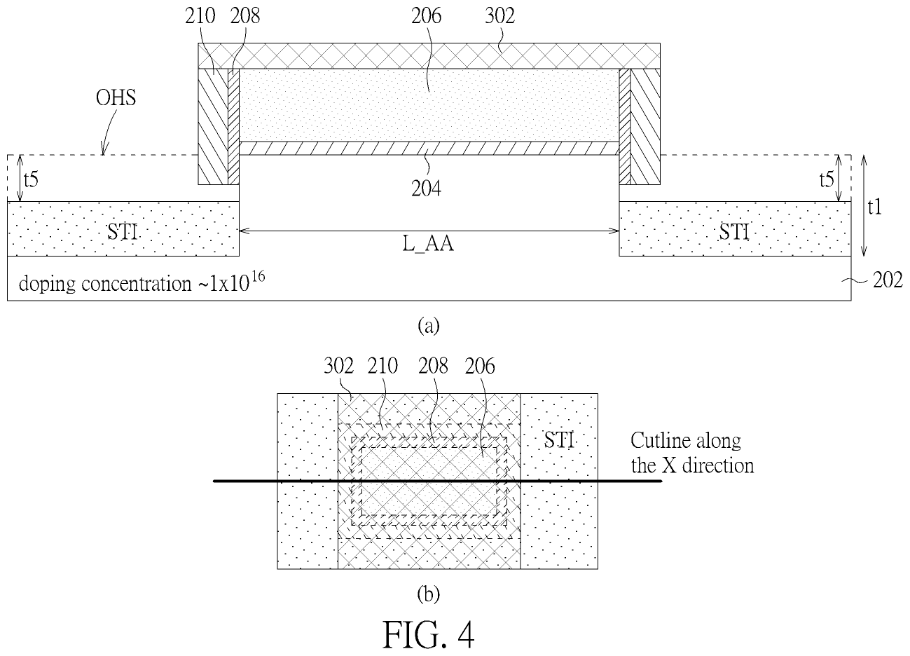

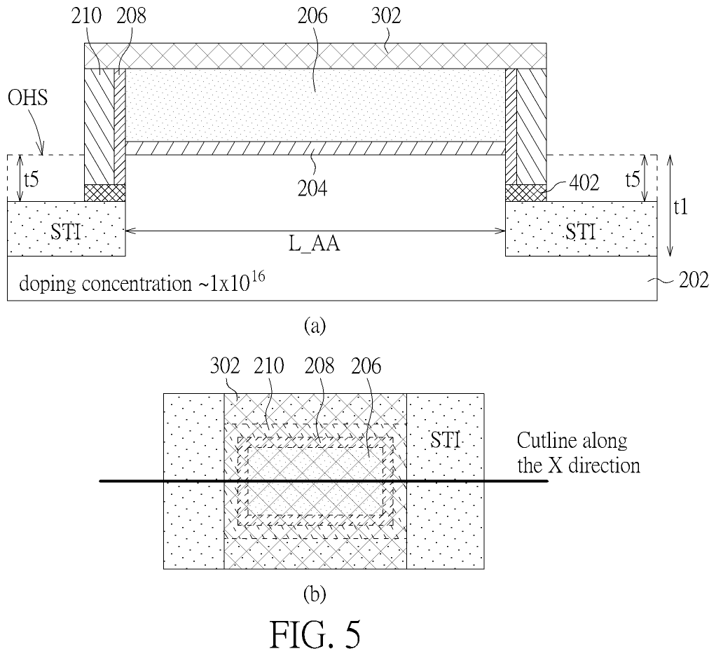

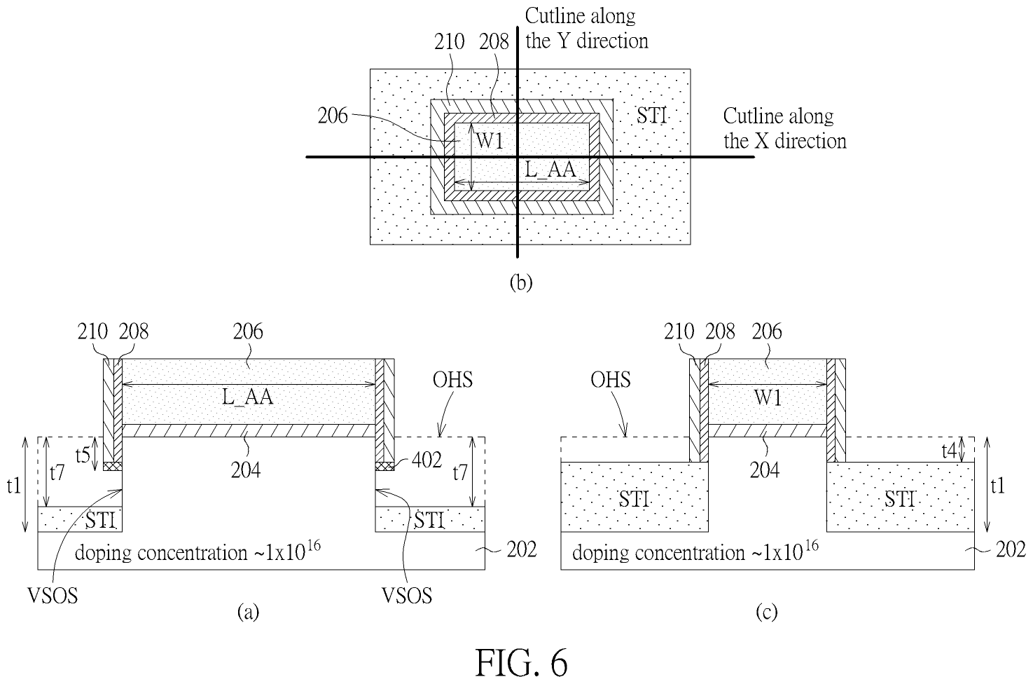

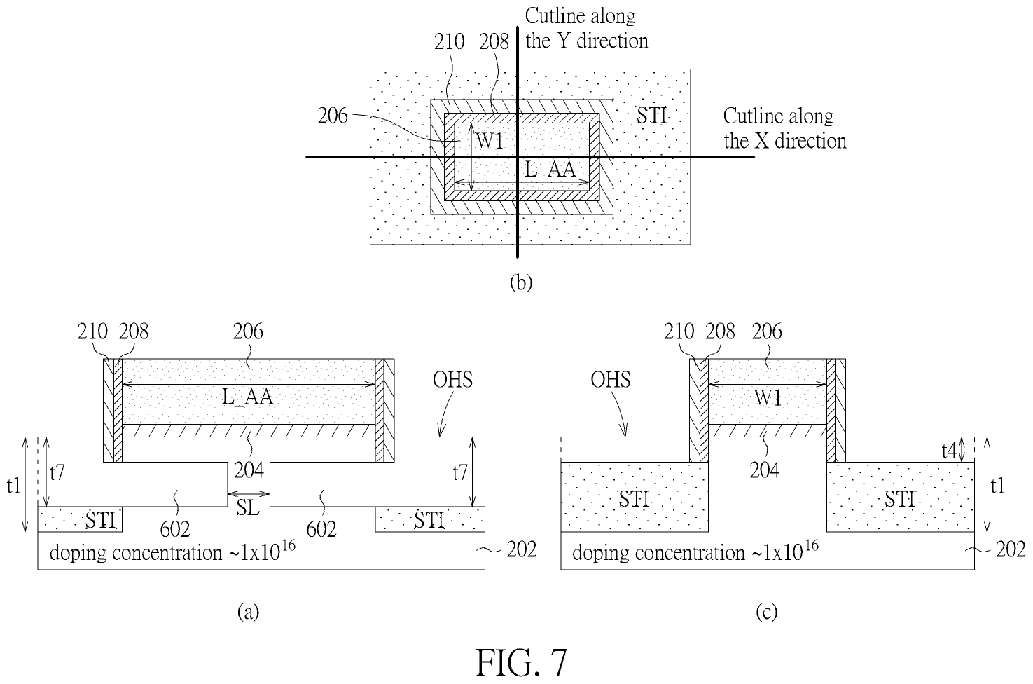

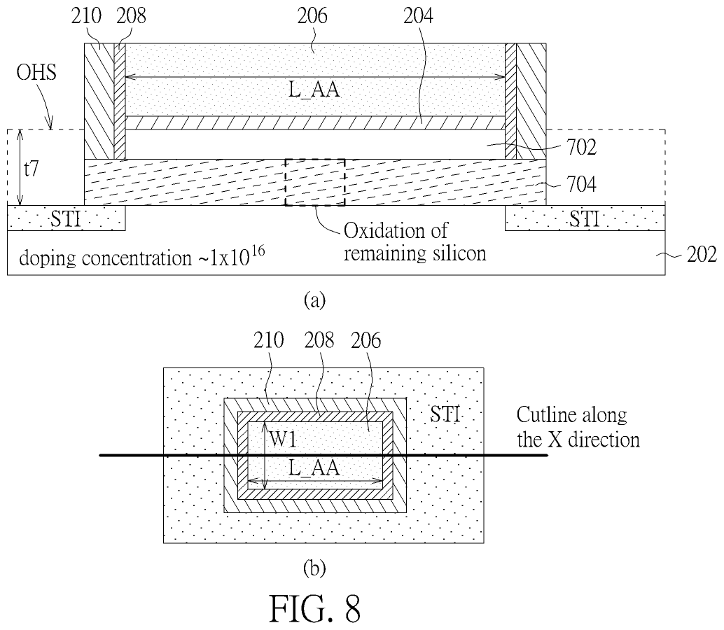

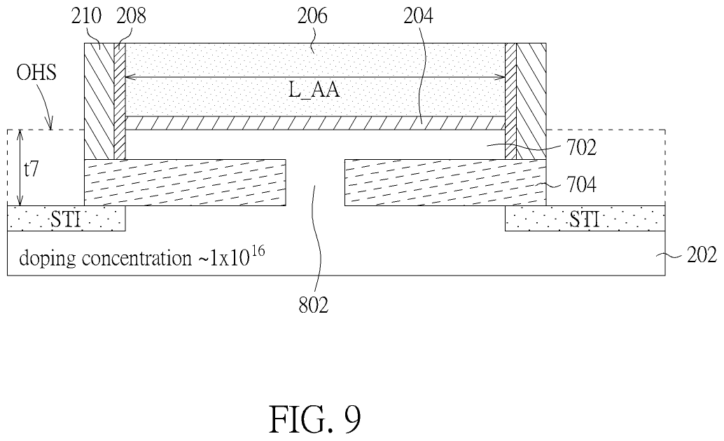

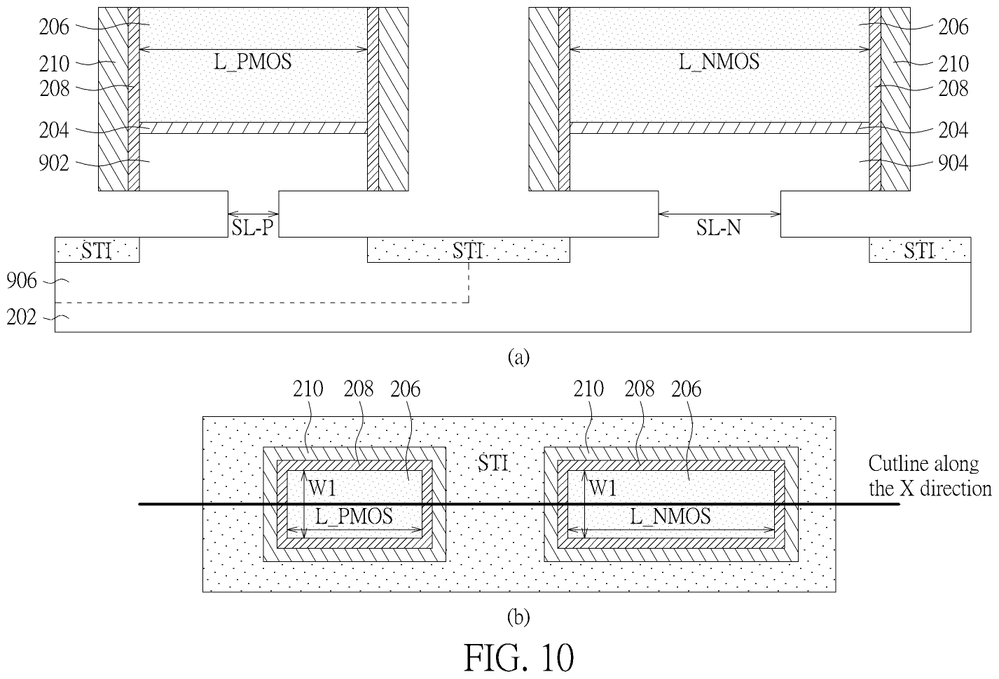

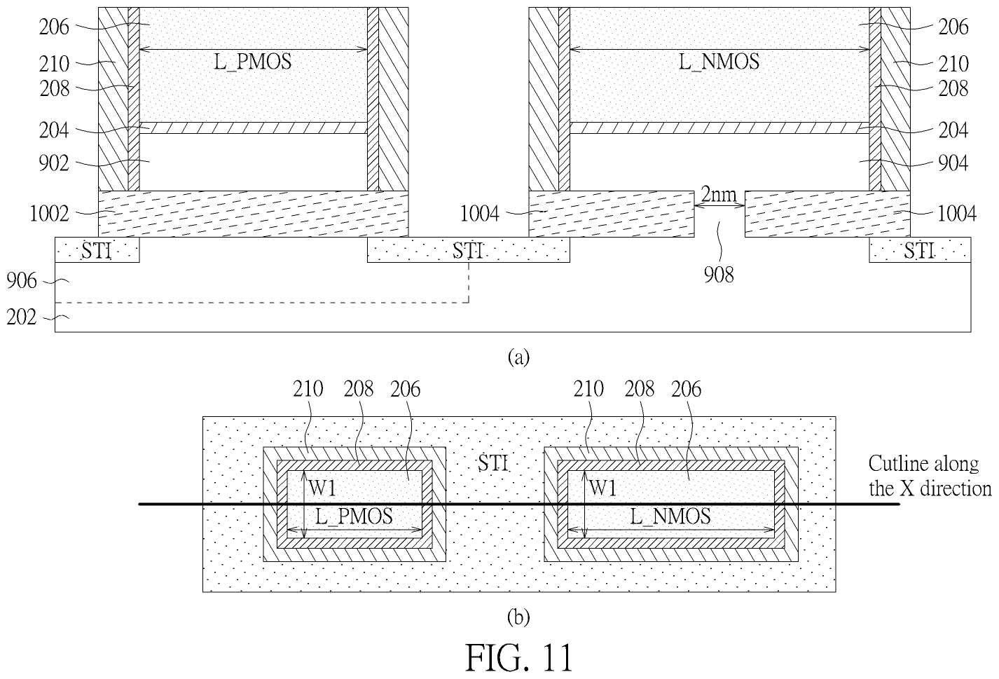

Please refer to FIG. 2B, FIG. 4, FIG. 5, FIG. 6, FIG. 7, FIG. 8, FIG. 9. Step 30 could include:

Step 102: Use the mask 302 to cover the oxide spacer-2 208 and the nitride spacer-2 210 along the length L_AA of the active region and etch down the STI (Shallow Trench Isolation) (FIG. 4).

Step 104: Deposit and etch down the SiCOH 402, and anisotropic etch the SiCOH 402 to reveal the STI (FIG. 5).

Step 106: Etch down the STI not covered by the mask 302 (FIG. 6).

Step 108: Use the lateral etching technique to remove the silicon underneath the active region to form cavities under the active region (FIG. 7).

Step 110: Fully (or not fully) oxidizing the remaining silicon portion underneath the active region and deposit oxide within the concaves (FIG. 8 & FIG. 9).

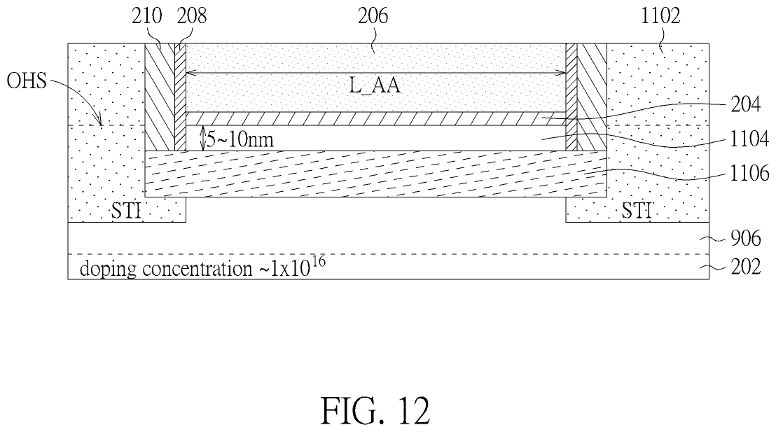

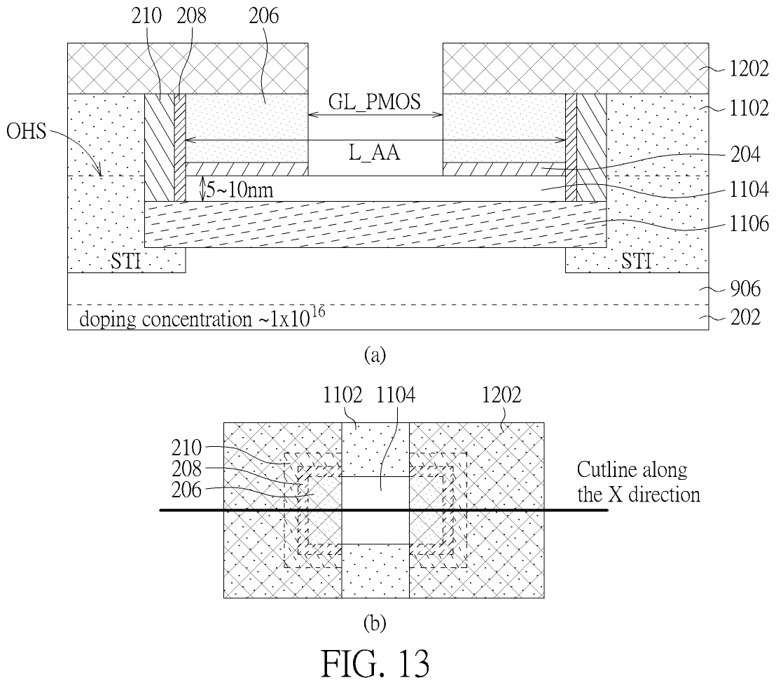

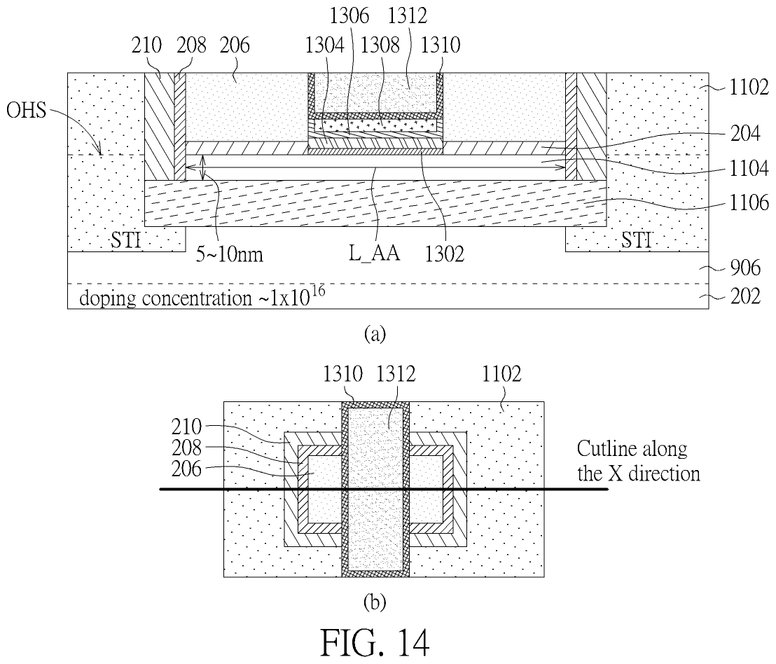

Then, please refer to FIG. 2C, FIG. 12, FIG. 13, FIG. 14. Step 40 could include:

Step 112: Deposit STI-oxide 1102 and use the CMP (chemical mechanical polishing or planarization) technology to align the STI-oxide 1102 to the top level of the pad-nitride layer 206 (FIG. 12).

Step 114: Define the gate region, etch the pad-nitride layer 206 and the pad-oxide layer 204 in the defined gate region, remove the nitride spacer-2 210 and the oxide spacer-2 208 in the defined gate region, and etch down the STI-oxide 1102 in the defined gate region (FIG. 13).

Step 116: Remove the photo-resistance, form gate oxide 1302, then deposit and etch back N+ polysilicon 1304, then deposit the gate conductive layer, and deposit the gate cap layer (FIG. 14).

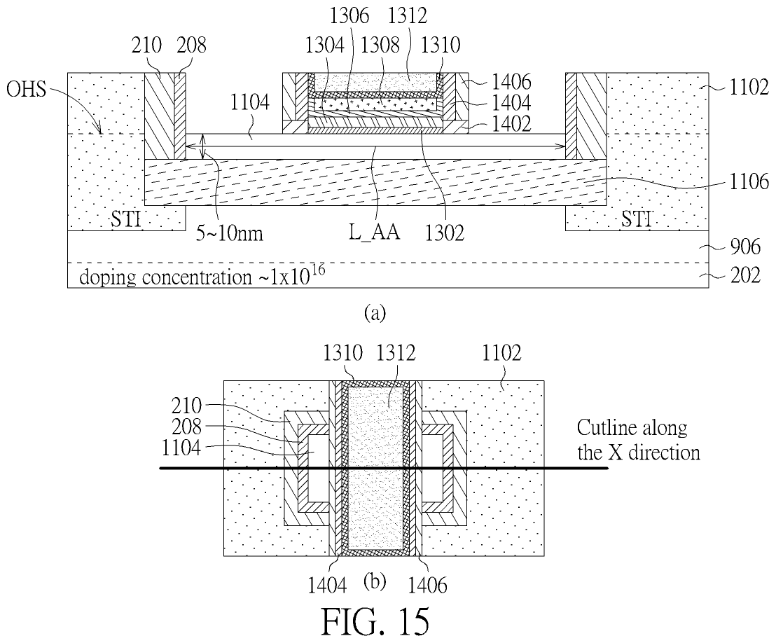

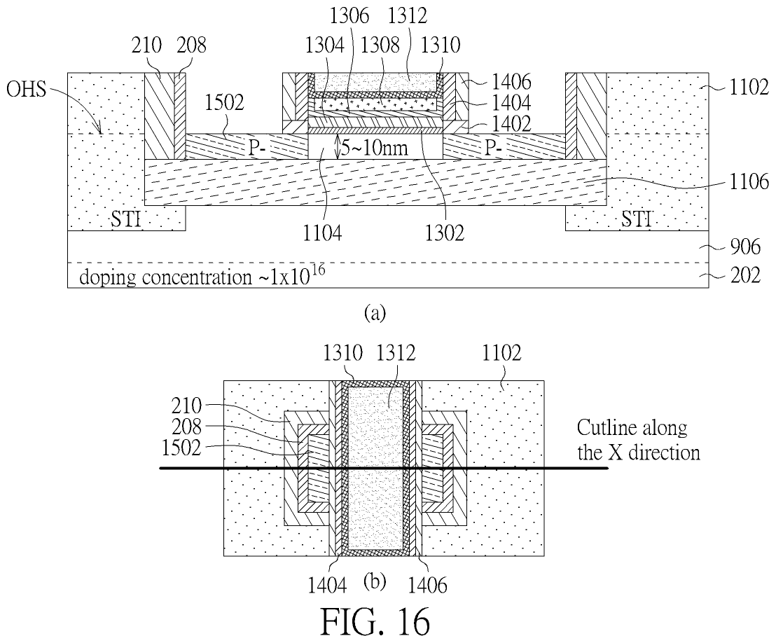

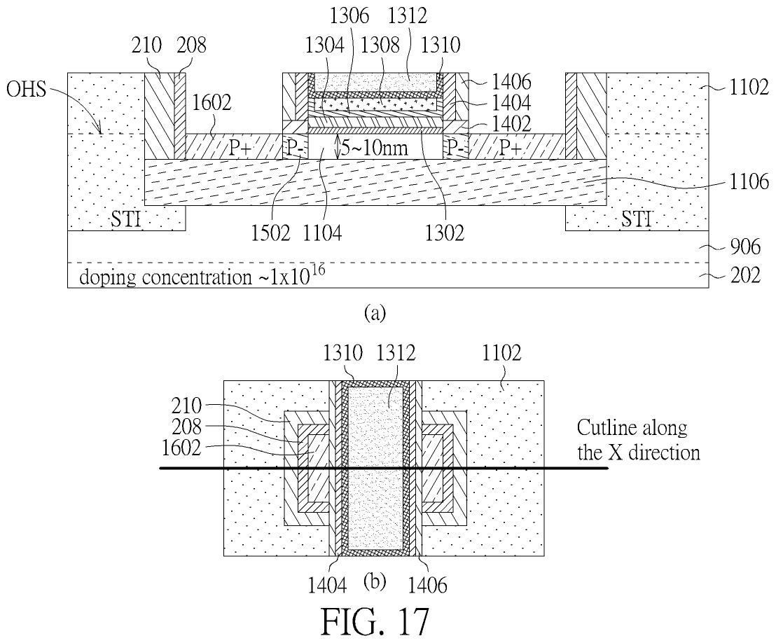

Then, please refer to FIG. 2D, FIG. 15, FIG. 16, FIG. 17. Step 50 to form exemplary source region and drain region could include:

Step 118: Etch the pad-nitride layer 206 and the pad-oxide layer 204 to reveal the silicon surface. Thermally grow very thin oxide-1 layer 1402 based on the revealed silicon surface, form a thin oxide-2 spacer 1404 and form thin nitride-1 spacer 1406, then etch the very thin oxide-1 layer 1402 outside the thin nitride-1 spacer 1406 (FIG. 15).

Step 120: Form and activate P− regions 1502 (FIG. 16).

Step 122: Form and activate the P+ regions 1602 to complete the PMOS transistor (FIG. 17).

In Step 20, as shown in FIG. 3 (a), use a typical Bulk Silicon wafer (either p-type or n-type) as the entire semiconductor substrate for construction of integrated circuits in multiple dice on this wafer, wherein the present invention uses a p-type silicon substrate 202 as an example and the p-type silicon substrate 202 has a doping concentration close to 1×10\hat{ }16 dopants/cm³. Adopt the well-known normal processes to create rectangular single-crystalline silicon active region covered by the pad-oxide layer 204 and then the pad-nitride layer 206 (wherein the active region has a dimension of length L_AA×width W1, and the length L_AA is greater than the width W1) over the original semiconductor surface (OSS) (or original horizontal surface (OHS), and outside these active regions use the well-known techniques to form STI (Shallow Trench Isolation) (the depth t1) surrounding the active region, wherein the STI is an oxide region and the STI has the depth t1. In one embodiment of the present invention, top surface of the STI can be leveled up to a top surface of the pad-nitride layer 206.

As shown in FIG. 3 (a), etch down the STI surrounding the active region from the OHS about a thickness of t4 to reveal sidewalls of the p-type silicon substrate 202, and form an oxide spacer-2 208 and a nitride spacer-2 210 to cover the sidewalls of the pad-oxide layer 204, the pad-nitride layer 206 and the revealed silicon substrate. In addition, FIG. 3 (b) is a top view corresponding to FIG. 3 (a), wherein FIG. 3 (a) is a cross-section view along a cutline of an X direction shown in FIG. 3 (b).

In Step 102, as shown in FIG. 4 (a) and FIG. 4 (b), then use the mask 302, such as photo-resistance, to cover the oxide spacer-2 208 and the nitride spacer-2 210 along the length L_AA, but not to cover the vertical sidewalls of oxide spacer-2 208 and the nitride spacer-2 210 along the width W1. Afterward, further etch down the STI not covered by the mask 302 such that the distance between the top of the etched STI and the original horizontal surface (OHS) is around t5. There is gap between the bottom of the nitride spacer-2 210 and the STI. In addition, FIG. 4 (b) is a top view corresponding to FIG. 4 (a), wherein FIG. 4 (a) is a cross-section view along a cutline of an X direction shown in FIG. 4 (b).

In Step 104, as shown in FIG. 5 (a), then deposit the SiCOH 402 at least to fill in the gap between the bottom of the nitride spacer-2 210 and the STI, etch down the SiCOH 402 to the OHS, and anisotropic etch the SiCOH 402 to reveal the STI. In addition, FIG. 5 (b) is a top view corresponding to FIG. 5 (a), wherein FIG. 5 (a) is a cross-section view along a cutline of an X direction shown in FIG. 5 (b).

In Step 106, as shown in FIG. 6 (a), afterward further etch down the STI not covered by the mask 302 such that the distance between the top of the etched STI and the original horizontal surface (OHS) is around t7, and then the mask 302 is removed. As shown in FIG. 6 (a), a vertical silicon sidewall with a depth of (t7-t5), called as VSOS (Vertical Silicon Oxidation Seed), is well exposed as the seed of the subsequent silicon etching process. However, in FIG. 6 (b), no such VSOS is revealed because the silicon sidewalls along the Y direction is protected by the oxide spacer-2 208 and the nitride spacer-2 210. Therefore later on the subsequent etching process will only etch the silicon along the X direction, rather than the silicon along the Y direction. In addition, FIG. 6 (b) is a top view corresponding to FIG. 6 (a), wherein FIG. 6 (a) is a cross-section view along a cutline of an X direction shown in FIG. 6 (b), and FIG. 6 (c) is a cross-section view along a cutline of a Y direction shown in FIG. 6 (b).

In Step 108, as shown in FIG. 7 (a), use the lateral etching technique to remove the silicon underneath the active region along the X direction (or other continuously oxidation/etching techniques) until a predetermined length SL of silicon is left. Here, cavities 602 (such as left cavity and right cavity) is formed as shown in FIG. 7 (a). Due to the oxide etching processes which may affect the original oxide spacer-2 208 covering the length direction (or X direction) of the active region, the width of the cavity along the width W1 of the active region may be not less than (or may be greater than) the width W1 of the active region. Again, as shown in FIG. 7 (c), the etching process will not etch the silicon along the Y direction. In addition, FIG. 7 (b) is a top view of the temporary structure, wherein FIG. 7 (a) is a cross-section view along a cutline of an X direction shown in FIG. 7 (b), and FIG. 7 (c) is a cross-section view along a cutline of a Y direction shown in FIG. 7 (b).

In Step 110, as shown in FIG. 8 (a), to fully isolate the silicon active region body 702 from the rest bulk semiconductor substrate (the p-type silicon substrate 202), the remaining silicon portion under the silicon active region body 702 could be fully oxidized first, and since the remaining silicon portion is fully oxidized, the width of the fully oxidized region along the width W1 of the active region (not including the oxide spacer-2 208) may be the same as the width W1 of the active region. As shown in FIG. 8 (a), then use CVD (chemical vapor deposition) process to deposit oxide to fill in the cavities 602 under the silicon active region body 702, and since the width of the cavity 602 along the width W1 of the active region may be not less than the width W1 of the active region, the width of the deposited oxide along the width W1 of the active region may be not less than the width W1 of the active region. Thus, as shown in FIG. 8 (a), a localized isolating layer 704 fully isolating the active region body 702 from the rest bulk semiconductor substrate is formed, and the width of the localized isolating layer 704 at the edges may be not less than the width at the middle of the localized isolating layer 704. In addition, FIG. 8 (b) is a top view corresponding to FIG. 8 (a), wherein FIG. 8 (a) is a cross-section view along a cutline of an X direction shown in FIG. 8 (b).

As shown in FIG. 9, on the other hand, in another embodiment, to leave a silicon opening 802 from which the carriers accumulated in the active region body 702 could leak into the rest bulk semiconductor substrate to improve the floating body effect, the oxidation process in FIG. 8 (a) could be skipped (or the remaining silicon portion under the silicon active region body 702 is just partially oxidized) and then use the CVD process to deposit oxide to fill in the cavities 602 under the silicon active region body 702.

Based on the previous embodiment, the present invention proposes a novel Oxide-PMOS Complementary Metal-Oxide-Semiconductor Field-Effect Transistor (OP-CMOSFET) structure based on a bulk semiconductor substrate, rather than a SOI structure, with localized isolating layers formed under the PMOS and NMOS, wherein the localized isolating layer under the PMOS fully isolates the PMOS active region body from the bulk semiconductor substrate.

As shown in FIG. 10 (a), in another embodiment, prepare two active regions for PMOS transistor and NMOS transistor respectively, wherein the length L PMOS of PMOS active region is shorter than the length L NMOS of NMOS active region. Then, following the processes mentioned in FIG. 3, FIG. 4, FIG. 5, FIG. 6, FIG. 7 a predetermined length SL-P of Silicon under PMOS active region body 902 is remained, and a predetermined length SL-N of Silicon under NMOS active region body 904 is remained. Because the length L PMOS of the PMOS active region is shorter than the length L NMOS of the NMOS active region, after the processes shown in FIG. 3, FIG. 4, FIG. 5, FIG. 6, FIG. 7 are executed, it is clear that the predetermined length SL-N of Silicon is greater than the predetermined length SL-P of Silicon. In addition, as shown in FIG. 10 (a), the PMOS transistor is formed in an N well 906. In addition, FIG. 10 (b) is a top view corresponding to FIG. 10 (a), wherein FIG. 10 (a) is a cross-section view along a cutline of an X direction shown in FIG. 10 (b).

As shown in FIG. 11 (a), then the remaining Silicon portion under the PMOS active region body 902 is fully oxidized, but only part of remaining Silicon portion under the NMOS active region body 904 is oxidized with an silicon opening 908 left around 1˜3 nm, such as 2 nm. Furthermore, use CVD process to deposit oxide to fill in the cavities under the PMOS active region body 902 and the NMOS active region body 904, and then etch back. Thus, a localized isolation layer 1002 fully isolating the PMOS active region body 902 from the rest bulk semiconductor substrate is formed, but the localized isolation layer 1004 under the NMOS active region body 904 has the silicon opening 908 left (around 1˜4 nm, such as 1˜3 nm, or 2 nm), such that the NMOS active region body 904 is still electrically coupled to the rest bulk semiconductor substrate. In addition, FIG. 11 (b) is a top view corresponding to FIG. 11 (a), wherein FIG. 11 (a) is a cross-section view along a cutline of an X direction shown in FIG. 11 (b).

Thus, the localized isolating layer 1002 under the PMOS transistor fully isolates the PMOS active region body 902 from the bulk semiconductor substrate, but the localized isolating layer 1004 under the NMOS transistor may not fully isolate the NMOS active region body 904 from the bulk semiconductor and leave the silicon opening 908 from which the electrons accumulated in the NMOS active region body 904 could leak into the bulk semiconductor substrate (the p-type silicon substrate 202) to improve the floating body effect. Later on, the PMOS transistor (s) (no matter one or more planar transistors or Fin-structure transistors) could be formed based on the PMOS active region body 902, so is the NMOS transistor (s) (no matter one or more planar transistors or Fin-structure transistors) formed based on the NMOS active region body 904. Before forming the transistors, the oxide spacer-2 208 and nitride spacer-2 210 could be selective removed in advance.

The following embodiment introduces exemplary manufacture processes for Fin-structure transistors formed in the PMOS active region body and/or NMOS active region body. To form the PMOS transistor, the NMOS active region in FIG. 10 or FIG. 11 could be protected first by mask and only reveal PMOS active region. Then, as shown in FIG. 12 which only illustrates the PMOS active region, STI-oxide 1102 is deposited and use the CMP (chemical mechanical polishing or planarization) technology to align the STI-oxide 1102 to the top level of the pad-nitride layer 206. The vertical length of the PMOS active region body 1104 (or the silicon channel) could be 5˜10 nm, wherein a localized isolating layer 1106 fully isolates the active region body 702 from the rest bulk semiconductor substrate.

As shown in FIG. 13 (a), use the photo-resistance 1202 as a mask to define the gate region with a length of GL PMOS, etch the pad-nitride layer 206 and the pad-oxide layer 204 in the defined gate region, remove the nitride spacer-2 210 and the oxide spacer-2 208 in the defined gate region, and etch down the STI-oxide 1102 in the defined gate region to form the step-structure in the gate region. The rest nitride spacer-2 210 and oxide spacer-2 208 surrounding the active region may strength the active region and prevent the active region from collapse in the event the active region is a narrow Fin or convex structure. In addition, FIG. 13(b) is a top view corresponding to FIG. 13 (a), wherein FIG. 13 (a) is a cross-section view along a cutline of an X direction shown in FIG. 13 (b).

As shown in FIG. 14 (a), remove the photo-resistance 1202, and form gate oxide 1302 (or Hi-K gate dielectric layer). Then deposit the N+ polysilicon 1304 and etch back, use atomic layer deposition (ALD) technology to form the Ti/TiN metal layer 1306, deposit Tungsten 1308, and use CMP technology against the Tungsten 1308, the Ti/TiN metal layer 1306 and then etch back. Therefore, the gate conductive layer (the Tungsten 1308 and the Ti/TiN metal layer 1306) is formed. Then deposit the cap nitride layer 1310 and the cap oxide layer 1312, and CMP the cap oxide layer 1312 and the cap nitride layer 1310. Therefore, the gate cap layer (the cap oxide layer 1312 and the cap nitride layer 1310) over the gate conductive layer (the Tungsten 1308 and the Ti/TiN metal layer 1306) is formed. In the event there is a gate last process, the gate conductive layer and the gate cap layer in the above-mentioned could be replaced by other suitable materials later. In addition, FIG. 14 (b) is a top view corresponding to FIG. 14 (a), wherein FIG. 14 (a) is a cross-section view along a cutline of an X direction shown in FIG. 14 (b).

As shown in FIG. 15 (a), to form the exemplary source and drain regions, the pad-nitride layer 206 and the pad-oxide layer 204 are removed first to define the source and drain regions to reveal silicon surface. Then, thermally grow very thin oxide-1 layer 1402 based on the revealed silicon surface, deposit oxide and anisotropic etch the oxide to form a thin oxide-2 spacer 1404, deposit nitride and anisotropic etch the nitride to form thin nitride-1 spacer 1406, then etch the very thin oxide-1 layer 1402 outside the thin nitride-1 spacer 1406. In addition, FIG. 15 (b) is a top view corresponding to FIG. 15 (a), wherein FIG. 15 (a) is a cross-section view along a cutline of an X direction shown in FIG. 15 (b).

As shown in FIG. 16 (a), then deposit lightly boron doped layer in the defined source and drain regions, use thermal diffusion to diffuse boron into the PMOS active region body 1104, and activate the P-regions 1502. Since the vertical length of the PMOS active region body (or the silicon channel) 1104 is 5˜10 nm, in one example the P-regions 1502 will abut against the localized isolation layer 1106 which fully isolates the PMOS active region body 1104 from the bulk substrate (i.e. the N well 906). Furthermore, with suitable temperature, the P-regions 1502 will also laterally diffuse, and part of the P-regions 1502 are under the gate spacers (the thin nitride-1 spacer 1406 and the thin oxide-2 spacer 1404). In addition, FIG. 16 (b) is a top view corresponding to FIG. 16 (a), wherein FIG. 16 (a) is a cross-section view along a cutline of an X direction shown in FIG. 16 (b).

As shown in FIG. 17 (a), thereafter deposit heavily boron doped layer in the defined source and drain regions, similarly use thermal diffusion to diffuse boron into the PMOS active region body 1104, and activate the P+ regions 1602 to complete the PMOS transistor. Again, since the vertical length of the PMOS active region body (or the silicon channel) 1104 is 5˜10 nm, the P+ regions 1602 will abut against the localized isolation layer 1106 which fully isolates the PMOS active region body 1104 from the bulk substrate (i.e. the N well 906). Furthermore, with suitable temperature, the P+ regions 1602 may only laterally diffuse a little bit, and part of the P− regions 1502 are still under the gate spacers (the thin nitride-1 spacer 1406 and the thin oxide-2 spacer 1404). Then the metal plugs (not shown) can be formed and filled in the cavities above the P+ regions 1602 to contact the P+ regions 1602. In addition, FIG. 17 (b) is a top view corresponding to FIG. 17 (a), wherein FIG. 17 (a) is a cross-section view along a cutline of an X direction shown in FIG. 17 (b). Since the top of the STI-oxide 1102 is raised up and higher than the OHS as previously mentioned (as shown in FIG. 17 (a), the top of the STI-oxide 1102 could be aligned with the top of the cap oxide layer 1312), later on the metal contact for the source/drain could be easily deposited within the concave between the raised STI-oxide 1102 and the gate.

To form the NMOS transistor, the PMOS active region could be then protected by mask and only reveal NMOS active region. As shown in FIG. 18 (a), FIG. 18 (a) only illustrates the NMOS active region, STI-oxide 1702 is deposited again, and use CMP technology to align the STI-oxide 1702 to the level of the pad-nitride layer 206. The vertical length of the NMOS active region body (or the silicon channel) 1704 is 5˜10 nm. Use the photo-resistance 1706 as a mask to define the gate region with a length of GL NMOS. In addition, as shown in FIG. 18 (a), the localized isolating layer 1708 under the NMOS active region body 1704 does not fully isolate the NMOS active region body 1704 from the p well 1712 and leave the silicon opening 1710. In addition, FIG. 18 (b) is a top view corresponding to FIG. 18 (a), wherein FIG. 18 (a) is a cross-section view along a cutline of an X direction shown in FIG. 18 (b).

Next, as shown in FIG. 19 (a), the following the similar processes from FIG. 13, FIG. 14, FIG. 15, FIG. 16, FIG. 17 (except that the doped layer is phosphorous doped layer, resulting in the N-regions 1802 and the N+regions 1804 being formed), the NMOS transistor could be formed. Then the metal plugs (not shown) can be formed and filled in the cavities to contact the N+ regions. In addition, FIG. 19 (b) is a top view corresponding to FIG. 19 (a), wherein FIG. 19 (a) is a cross-section view along a cutline of an X direction shown in FIG. 19 (b).

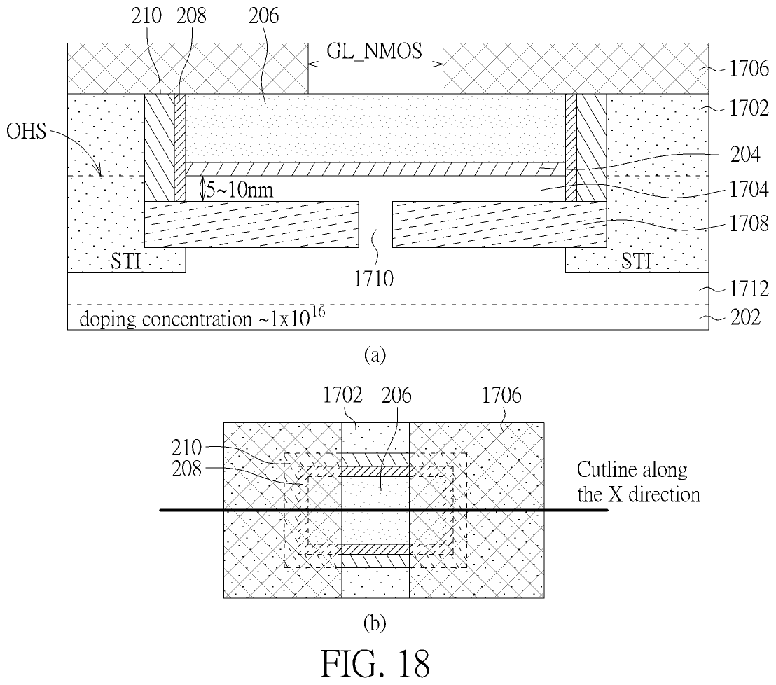

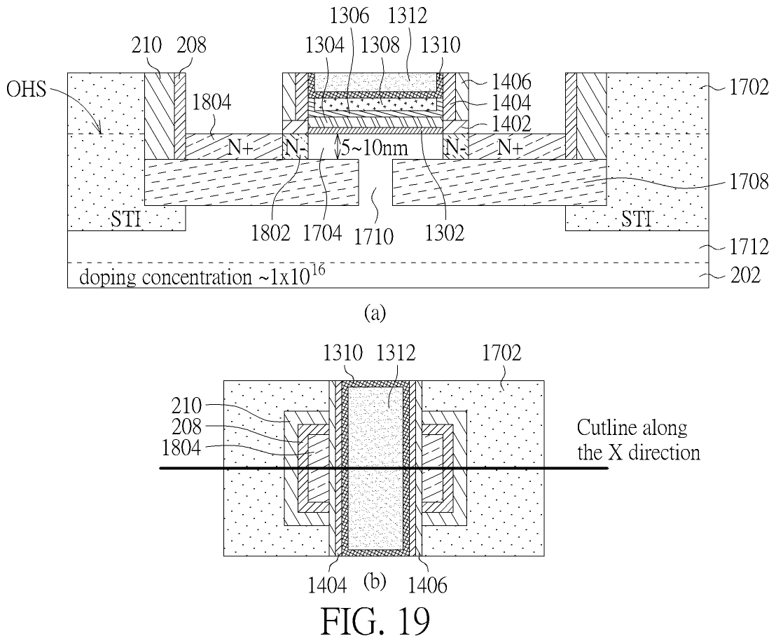

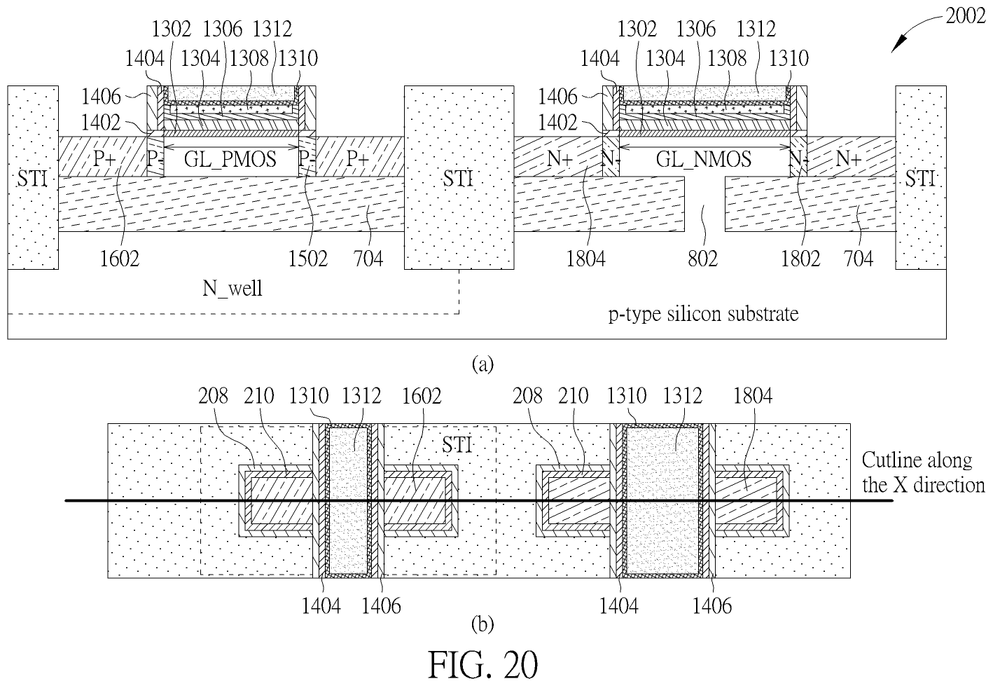

Therefore, a novel Oxide-PMOS Complementary Metal-Oxide-Semiconductor Field-Effect Transistor (OP-CMOSFET) 2022 based on a bulk semiconductor substrate, rather than a SOI structure, is shown in FIG. 20. As shown in FIG. 20 (a), the OP-CMOSFET 2002 has localized isolating layers formed under the PMOS transistor and NMOS transistor respectively, thus the leakage current and latch up issues could be improved. Moreover, the localized isolating layer under the PMOS transistor fully isolates the PMOS active region body from the bulk semiconductor substrate. However, the localized isolating layer under the NMOS transistor only partially isolates the NMOS active region body from the bulk semiconductor substrate. As shown in FIG. 20 (a), the localized isolating layer under the NMOS active region body has a silicon opening 802 left, such that the NMOS active region body is still electrically coupled to the rest bulk semiconductor substrate. Thus, the floating body effect in the NMOS transistor could be improved. In addition, FIG. 20 (b) is a top view corresponding to FIG. 20 (a), wherein FIG. 20 (a) is a cross-section view along a cutline of an X direction shown in FIG. 20 (b).

As shown in FIG. 21, the present invention could be also applied to Oxide-NMOS Complementary Metal-Oxide-Semiconductor Field-Effect Transistor (ON-CMOSFET) 2102 based on a bulk semiconductor substrate, rather than a SOI structure. The ON-CMOSFET 2102 has localized isolating layers formed under the PMOS transistor and NMOS transistor respectively to improve the leakage current and latch up issues. Moreover, the localized isolating layer under the NMOS transistor fully isolates the NMOS active region body from the bulk semiconductor substrate. However, the localized isolating layer under the PMOS transistor only partially isolates the PMOS active region body from the bulk semiconductor substrate, such that the PMOS active region body is still electrically coupled to the rest bulk semiconductor substrate. Thus, the floating body effect in the PMOS transistor could be improved.

Of course, in another embodiment of the present invention, Partial-Oxide Complementary Metal-Oxide-Semiconductor Field-Effect Transistor (PO-CMOSFET) 2202 is proposed as shown in FIG. 22. The PO-CMOSFET 2202 has localized isolating layers formed under the PMOS transistor and NMOS transistor respectively to improve the leakage current and latch up issues. Wherein the localized isolating layer under the NMOS transistor only partially isolates the NMOS active region body from the bulk semiconductor substrate, and the localized isolating layer under the PMOS transistor only partially isolates the PMOS active region body from the bulk semiconductor substrate. Therefore, the PMOS active region body and the NMOS active region body are still electrically coupled to the rest bulk semiconductor substrate. Thus, the floating body effect in the PMOS transistor and NMOS transistor could be improved.

Furthermore, in another embodiment of the present invention, Oxide-PMOS-NMOS Complementary Metal-Oxide-Semiconductor Field-Effect Transistor (OPN-CMOSFET) 2302 is proposed as shown in FIG. 23. The OPN-CMOSFET 2302 has localized isolating layers formed under the PMOS transistor and NMOS transistor respectively, thus the leakage current and latch up issues could be improved. Both the localized isolating layer under the NMOS transistor fully isolates the NMOS active region body from the bulk semiconductor substrate, and the localized isolating layer under the PMOS transistor fully isolates the PMOS active region body from the bulk semiconductor substrate as well.

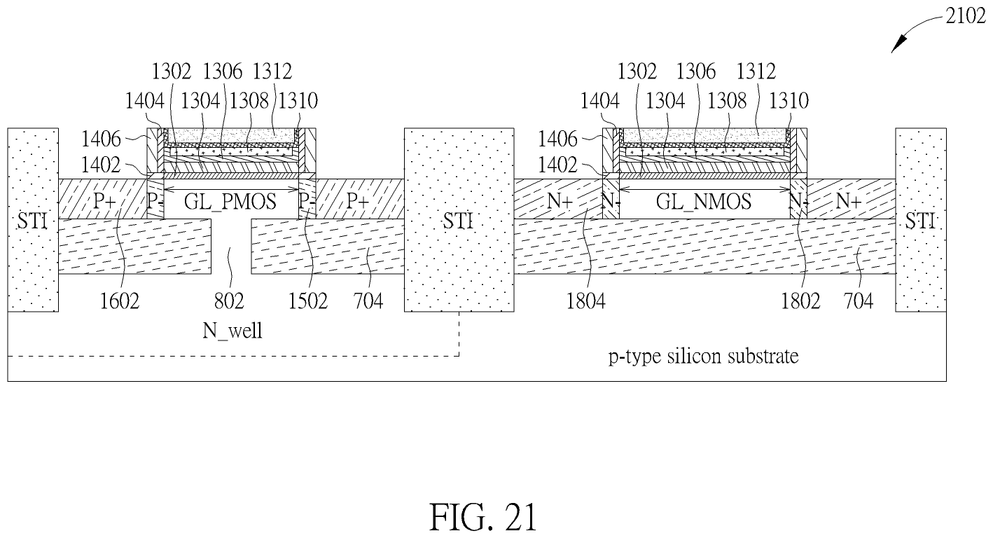

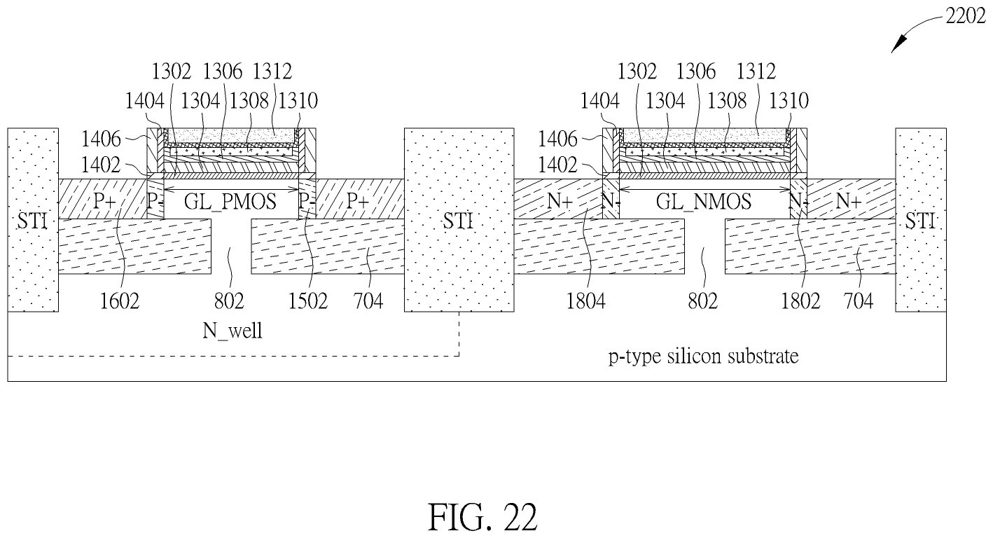

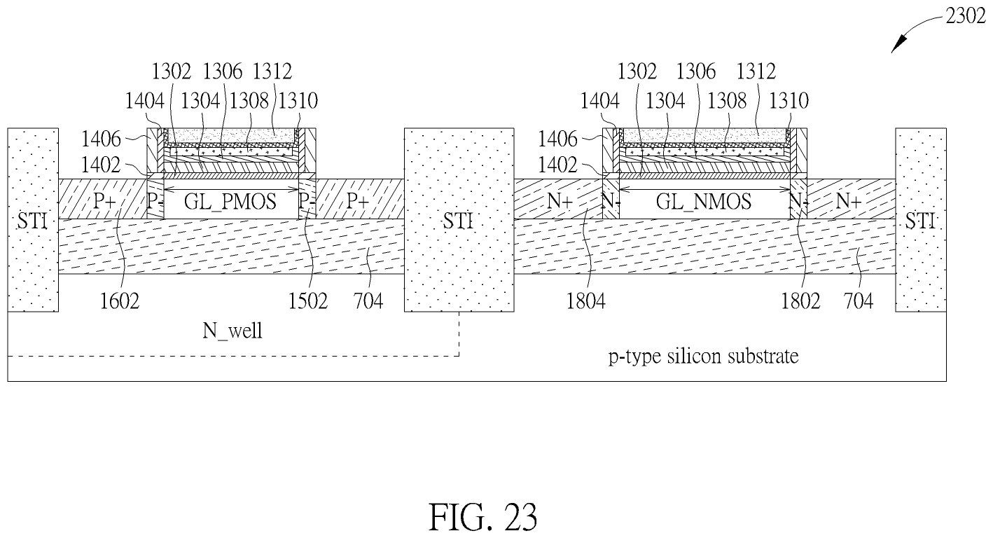

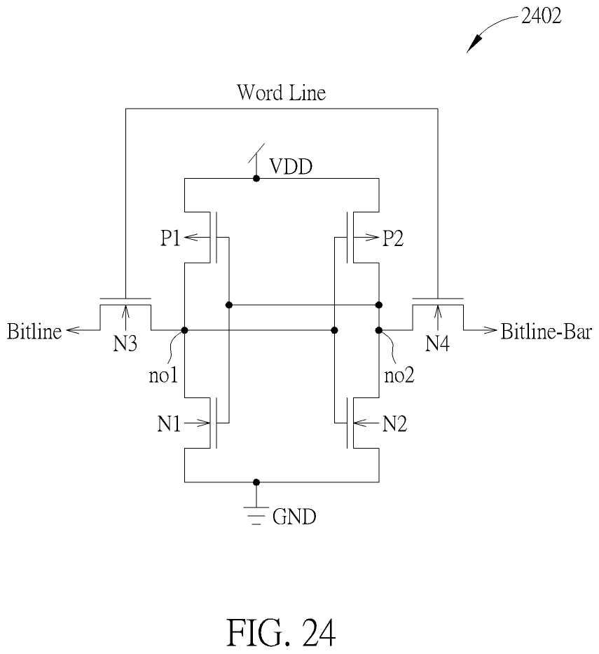

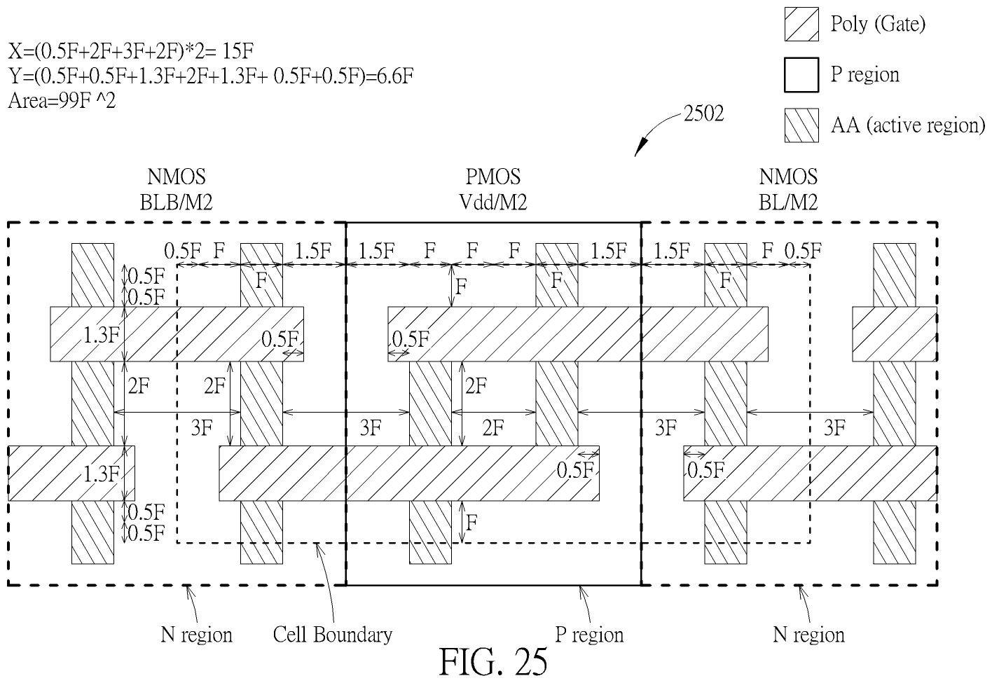

Moreover, the present invention could be applied to a SRAM structure 2402 of FIG. 24, wherein the SRAM structure 2402 has two PMOS transistors (P1, P2) and the two NMOS transistors (N1, N2) which are configured as Cross-Couple Diver Devices, and the other two NMOS transistors N3, N4 are used as Access Devices between the Bitline/Bitline-Bar and the two storage nodes (no1, no2). In the present invention, each of the four NMOS transistors N1, N2, N3, N4 is built into the p-type silicon substrate with partially isolating layer, such that the NMOS active region body of each NMOS transistor is still electrically coupled to the bulk substrate which is connect to a Ground Voltage. On the other hand, the two PMOS transistors P1, P2 have localized isolating layers to fully isolate the PMOS transistors from the bulk substrate. Therefore, the present invention can form localize isolating layers in the Bulk substrate without a need of buying an entire SOI Wafer which is very expensive. So between NMOS and PMOS transistors there is no need to reserve extra LUD (Latch-Up Distance) for achieving a CMOS configuration. There is no path for Current Flow to cause awkward Latch-up phenomena. As a result the CMOS SRAM cell size can be made more compactly and the more simplified circuit layout can be accomplished with much less area. The difficulties of making a compact 6 T CMOS SRAM cell 2502, circuit and layout design with better PPAC (power, performance, area, and cost) can be achieved. As shown in FIG. 25, two PMOS transistors are disposed in the P region 2504 under which a localized isolating layer extends along the longer edge of the P active region and partially or fully isolates the PMOS transistors from the bulk substrate. The NMOS transistors are disposed in the N region 2506 under which a localized isolating layer also extends along the longer edge of the N active region and partially or fully isolates the NMOS transistors from the bulk substrate The reserved latch up distance between the PMOS and NMOS transistors could be as low as 3 F (marked in the red dot ellipse). In this example, the gate length is 1.3 F, the width of the active region is 1 F, and the area of the SRAM is around 99 F², wherein F is minimum feature length of the technology node for manufacturing the compact 6 T CMOS SRAM cell 2502.

To sum up, the present invention has some advantages as follows:
1. The present invention can form localize isolating layers in the Bulk substrate without a need of buying an entire SOI Wafer which is very expensive.
2. With the localize isolating layers under the PMOS transistor and NMOS transistor, the leakage current and latch up issues in the CMOS structure could be improved.
3. The localize isolating layer under the PMOS transistor and/or NMOS transistor could partially isolate the PMOS transistor and/or NMOS transistor from the Bulk substrate, such that the floating body effect in the conventional SOI Wafer could be solved.
4. By using thermal diffusion of lightly/heavily doped layers to form the source/drain regions, there is no ion-implantation process for doping the Source/Drain regions.
5. Since the vertical length of the PMOS active region body/NMOS active region body is around 5˜10 nm, the reduction of the junction area of the source/drain regions n will also lead to the reduction of a leakage current.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A MOS (Metal-Oxide-Semiconductor) transistor comprising:
a bulk semiconductor substrate with a semiconductor surface;
an active region defined based on the bulk semiconductor substrate;
a gate structure within the active region and above the semiconductor surface;
a transistor body within the active region and under the semiconductor surface;
a source region electrically coupled to a channel region within the transistor body;
a drain region electrically coupled to the channel region within the transistor body; and
a localized isolating layer extending along the length of the active region and under the transistor body;
wherein the localized isolating layer at least partially isolates the transistor body from the bulk semiconductor substrate, and a bottom of the source region and a bottom of the drain region abut against the localized isolating layer.

2. The MOS transistor in claim 1, wherein a vertical length of the transistor body is 5˜10 nm, and a length of the active region is greater than a width of the active region.

3. The MOS transistor in claim 1, wherein the localized isolating layer fully isolates the transistor body from the bulk semiconductor substrate.

4. The MOS transistor in claim 1, wherein the localized isolating layer has a semiconductor opening from which the transistor body is electrically coupled to the bulk semiconductor substrate.

5. The MOS transistor in claim 4, wherein a width of the semiconductor opening along the length of the active region is 1˜3 nm.

6. The MOS transistor in claim 1, further comprising a shallow trench isolation region surrounding the active region and the localized isolating layer.

7. The MOS transistor in claim 1, further comprising a spacer structure at least partially surrounding the active region, wherein the spacer structure is encompassed by the shallow trench isolation region.

8. The MOS transistor in claim 7, wherein the spacer structure comprises an oxide spacer surrounding the active region and a nitride spacer surrounding the oxide spacer.

9. A CMOS (complementary Metal-Oxide-Semiconductor) circuit, comprising:
a bulk semiconductor substrate with an original semiconductor surface;
a first active region and a second active region formed based on the bulk semiconductor substrate;
a PMOS (p-type Metal-Oxide-Semiconductor) transistor formed in the first active region;
a first localized isolating layer under the PMOS transistor and at least partially isolating the PMOS transistor from the bulk semiconductor substrate;
an NMOS (n-type Metal-Oxide-Semiconductor) transistor formed in the second active region; and
a second localized isolating layer under the NMOS transistor and at least partially isolating the NMOS transistor from the bulk semiconductor substrate.

10. The CMOS circuit in claim 9, further comprising:
a first shallow trench isolation region surrounding the first active region and the first localized isolating layer; and
a second shallow trench isolation region surrounding the second active region and the second localized isolating layer.

11. The CMOS circuit in claim 9, wherein the first localized isolating layer fully isolates the PMOS transistor from the bulk semiconductor substrate, and the second localized isolating layer only partially isolates the NMOS transistor from the bulk semiconductor substrate.

12. The CMOS circuit in claim 11, wherein the second localized isolating layer has a semiconductor opening from which the NMOS transistor body is electrically coupled to the bulk semiconductor substrate.

13. The CMOS circuit in claim 9, wherein the first localized isolating layer only partially isolates the PMOS transistor from the bulk semiconductor substrate, and the second localized isolating layer fully isolates the NMOS transistor from the bulk semiconductor substrate.

14. The CMOS circuit in claim 13, wherein the first localized isolating layer has a semiconductor opening from which the PMOS transistor body is electrically coupled to the bulk semiconductor substrate.

15. The CMOS circuit in claim 9, wherein the first localized isolating layer fully isolates the PMOS transistor from the bulk semiconductor substrate, and the second localized isolating layer fully isolates the NMOS transistor from the bulk semiconductor substrate.

16. The CMOS circuit in claim 9, wherein:
a length of the first active region is greater than a width of the first active region, and the first localized isolating layer extends along the length of the first active region; and
a length of the second active region is greater than a width of the second active region, and the second localized isolating layer extends along the length of the second active region.

17. The CMOS circuit in claim 9, wherein the PMOS transistor comprises a transistor body under the original semiconductor surface, and a vertical length of the transistor body is 5˜10 nm.

18. The CMOS circuit in claim 17, wherein a bottom of the transistor body abuts against the first localized isolating layer.

19. A CMOS circuit, comprising:
a bulk semiconductor substrate with a first active region and a second active region;
a set of PMOS transistors formed in the first active region; and
a set of NMOS transistors formed in the second active region;
wherein a first localized isolation layer extends along the length of the first active region and at least partially isolates the PMOS transistors from the bulk semiconductor substrate;
wherein a second localized isolation layer extends along the length of the second active region and at least partially isolates the NMOS transistors from the bulk semiconductor substrate.

20. The CMOS circuit in claim 19, wherein the first localized isolating layer fully isolates the set of PMOS transistors from the bulk semiconductor substrate, and the second localized isolating layer only partially isolates the set of NMOS transistors from the bulk semiconductor substrate.

21. The CMOS circuit in claim 19, wherein a first STI (shallow trench isolation) region surrounds the first active region, and a second STI region surrounds the second active region.

22. The CMOS circuit in claim 21, wherein the CMOS circuit is a SRAM (static random-access memory) cell, and the distance between one PMOS transistor and one NMOS transistor adjacent to the one PMOS transistor is not greater than 3 F, wherein F is the minimum feature size.

23. The CMOS circuit in claim 19, wherein a length of the first active region is greater than a width of the first active region, and a length of the second active region is greater than a width of the second active region.
